(19) United States
(12) Patent Application Publication
(10) Pub. No.: US 2010/0096754 A1
(43) Pub. Date: Apr. 22, 2010

(54) Semiconductor package, semiconductor module, and method for fabricating the semiconductor package

(75) Inventors: Jonggi Lee, Yongin-si (KR); SunWon Kang, Seongnam-si (KR); Young Lyong Kim, Seongnam-si (KR); Jongho Lee, Hwaseong-si (KR); Chul-Yong Jang, Yongin-si (KR); Minill Kim, Cheonan-si (KR); Eunchul Ahn, Yongin-si (KR); Kwang Yong Lee, Anyang-si (KR); Seungduk Baek, Hwangseong-si (KR); Ji-Seok Hong, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,477

(22) Filed: Oct. 16, 2009

(30) Foreign Application Priority Data
Oct. 17, 2008 (KR) 10-2008-0102145
Nov. 6, 2008 (KR) 10-2008-0109862
Jun. 5, 2009 (KR) 10-2009-0049948

(51) Int. Cl. H01L 23/498; H01L 21/768

(52) U.S. Cl. 257/738; 438/613; 257/E21.589; 257/E23.069

(57) ABSTRACT

Provided is a semiconductor package, a semiconductor module and a method for fabricating the semiconductor package. The method provides a substrate including a bonding pad. The method forms a dielectric layer for exposing the bonding pad on the substrate. The method forms a redistribution line which is electrically connected to the bonding pad, on the dielectric layer. The method forms an external terminal which is electrically connected to the bonding pad without using a solder mask which limits a position of the external terminal, on the redistribution line.

### CROSS-REFERENCE TO RELATED APPLICATIONS

This application claims priority under 35 U.S.C. §119 to Korean Patent Application No. 10-2008-0102145, filed on Oct. 17, 2008, Korean Patent Application No. 10-2008-0109862, filed on Nov. 6, 2008, and Korean Patent Application No. 10-2009-0049948, filed on Jun. 5, 2009, the entire contents of each are hereby incorporated by reference in their entirety.

### BACKGROUND

1. Field

Example embodiments herein relate to a semiconductor device, and more particularly, to a semiconductor package, a semiconductor module and a method for fabricating the semiconductor package.

2. Description of the Related Art

In the semiconductor industry, techniques for miniaturizing and lightening semiconductor devices are being researched. In the conventional art, a package technology, called Chip Scale Package (CSP) or chip size package in which the size of semiconductor package is miniaturized to the size of the semiconductor chip level, is being developed. Furthermore, a technology for fabricating a wafer level package or a wafer level chip scale package, which simultaneously fabricates a plurality of semiconductor packages at a wafer level, is being developed. In a stage for fabricating the chip scale package or the wafer level package, however, a process for forming semiconductor chips or external terminals may be complicated.

### SUMMARY

Example embodiments provide a semiconductor package and a method for fabricating the same reliably while simplifying a fabrication process.

Example embodiments also provide a semiconductor package having a simpler structure and a method for fabricating the same.

Example embodiments also provide a semiconductor module using the semiconductor package, a memory card and an electronic device.

In accordance with example embodiments, a method for fabricating semiconductor package may include providing a substrate including a bonding pad, forming a dielectric layer on the substrate, the dielectric layer being configured to expose the bonding pad, forming a redistribution line on the dielectric layer, the redistribution line being configured to electrically connect to the bonding pad, and forming an external terminal on the redistribution line without using a solder mask.

In accordance with example embodiments, a semiconductor package may include a substrate including at least one bonding pad, a dielectric layer on the substrate, the dielectric layer being configured to expose a portion of the at least one bonding pad, at least one redistribution line on the dielectric layer, the at least one redistribution line being configured to electrically connect to the at least one bonding pad, and at least one external terminal on the at least one redistribution line, the at least one external terminal being electrically connected with the at least one bonding pad, and the at least one external terminal being formed without a solder mask limiting a disposition region on the at least one redistribution line.

Example embodiments provide a method for fabricating semiconductor package. The method according to example embodiments may include providing a substrate including a bonding pad, forming a dielectric layer for exposing the bonding pad on the substrate, forming a redistribution line which is electrically connected to the bonding pad, on the dielectric layer, and forming an external terminal which is electrically connected to the bonding pad without using a solder mask which limits a position of the external terminal, on the redistribution line.

In example embodiments, forming the redistribution line may include forming a bent line, and forming the external terminal may include forming a protrusion which is extended along the bent line and is limited in the bent line.

In example embodiments, forming the external terminal may include directly forming the external terminal with surface tension on the redistribution line without forming a region which limits a formation position of the external terminal by exposing a portion of the redistribution line.

In example embodiments, forming the external terminal may include attaching a solder ball onto the redistribution line, and applying at least one of heat and a magnetic field to the solder ball to perform the reflow of the solder ball.

In example embodiments, the heat may be applied by an induction heater which is adjusted at a frequency of 10 MHz or higher and a power of 2000 Watt or higher.

In example embodiments, forming the external terminal may include: providing a solder ball comprising a non-melting material having a first melting point and a melting material having a second melting point lower than the first melting point, to the redistribution line; and selectively melting the melting material.

In example embodiments, forming the external terminal may include selectively melting the melting material to restrictively wet the melting material at the redistribution line without melting the non-melting material.

In example embodiments, in the wetting of the melting material, the non-melting material may not be melted, and the selectively-melted melting material may not infinitely be wetted at the redistribution line by adhesive strength with the non-melting material.

In example embodiments, forming the external terminal may include heating the solder ball at an intermediate temperature between the first and second melting points.

In example embodiments, providing the solder ball may include attaching a solder ball having a structure in which the melting material surrounds the non-melting material, onto the redistribution line.

In example embodiments, the method of fabricating a semiconductor package may also include providing the external terminal the may further include exposing a portion of the external terminal, and forming a molding layer which covers the redistribution line.

In example embodiments, a semiconductor package may includes a substrate including a bonding pad, a dielectric layer disposed on the substrate, exposing a portion of the bonding pad, a redistribution line disposed on the dielectric layer, and electrically connected to the bonding pad, and a plurality of external terminals disposed on the redistribution line to be electrically connected with the bonding pad, and directly formed without a solder mask limiting a disposition position on the redistribution line.

In example embodiments, the redistribution line may include a bent line having a width of a size less than a size of the external terminal, and the external terminal may include a protrusion which is restrictively disposed at the bent line.

In example embodiments, the protrusion may protrude along an extension direction of the redistribution line.

In example embodiments, the external terminal may include an outer layer outer layer having a relatively low melting point, the outer layer surrounding an inner core having a melting point higher than the melting point of the outer layer.

In example embodiments, the inner core may include a first metal, a refractory resin, and a combination of these, and the outer layer may include a second metal having a melting point less than a melting point of the first metal.

In example embodiments, the inner core may include any one of copper (Cu), nickel (Ni), molybdenum (Mo), tungsten (W), tantalum (Ta), niobium (Nb), polyamideimide, polyetherimide, polyethersulfone, polyarylate, polyphenylenesulfide, polyetheretherketone, polysulfone, and a combination thereof; and the outer layer may include any one of Pb, Pb/Sn, Sn/Zn, Sn/Bi, Sn/Ag, Sn/Zn/Bi, Sn/Ag/Cu, Sn/Bi/Ag/In, and a combination thereof.

In example embodiments, the semiconductor package may further include a molding layer exposing a portion of the external terminal, and covering the redistribution line.

In example embodiments, a semiconductor module may include a module substrate; and at least one semiconductor package mounted on the module substrate, wherein the at least one semiconductor package may includes a package substrate including at least one bonding pad, a dielectric layer disposed on the package substrate, exposing a portion of the at least one bonding pad, at least one redistribution line disposed on the dielectric layer, and electrically connected to the at least one bonding pad, at least one external terminal electrically connected to the at least one bonding pad, and directly formed without a solder mask limiting a disposition position on the redistribution line, and a molding layer disposed on the dielectric layer to cover the redistribution line, exposing a portion of the external terminal, wherein the at least one semiconductor package is electrically connected to the module substrate through the at least one external terminal.

In example embodiments, the at least one external terminal may include a solder ball including at least one protrusion which extends along the at least one redistribution line, or a solder ball having a multi structure including an outer layer surrounding an inner core, the inner core having a melting point higher than a melting point of the outer layer.

### BRIEF DESCRIPTION OF THE DRAWINGS

Example embodiments will be more clearly understood from the following detailed description taken in conjunction with the accompanying drawings. FIGS. 1-36 represent non-limiting, example embodiments as described herein.

FIG. 1 is a plan view illustrating a semiconductor package according to example embodiments;

FIG. 2 is a cross-sectional view illustrating a portion of the semiconductor package in FIG. 1;

FIGS. 3 and 4 are plan views magnifying a portion of the semiconductor package in FIG. 1;

FIG. 5 is a perspective view illustrating a semiconductor package according example embodiments;

FIG. 6 is a perspective view illustrating a semiconductor package according to example embodiments;

FIG. 7 is a cross-sectional view taken alone line VII-VII′ in the semiconductor package in FIG. 6;

FIG. 8 is a perspective view illustrating a semiconductor package according to example embodiments;

FIG. 9 is a cross-sectional view taken alone line IX-IX′ in the semiconductor package in FIG. 8;

FIG. 10 is a perspective view illustrating a semiconductor package according to example embodiments;

FIG. 11 is a plan view illustrating a semiconductor module according to example embodiments;

FIG. 12 is a plan view illustrating a semiconductor module according to example embodiments;

FIG. 13 is a flowchart illustrating a method for fabricating a semiconductor package according to example embodiments;

FIGS. 14 through 19 are cross-sectional views illustrating a method for fabricating a semiconductor package according to example embodiments;

FIG. 20 is a perspective view illustrating a method for fabricating a semiconductor package according to example embodiments;

FIG. 21 is a flowchart illustrating a method for fabricating a semiconductor package according to example embodiments;

FIG. 22 is a plan view illustrating a method for fabricating a semiconductor package according to example embodiments;

FIG. 23 is a cross-sectional view illustrating a semiconductor package according to example embodiments;

FIGS. 24 through 27 are cross-sectional views illustrating a method for fabricating the semiconductor package according to example embodiments;

FIG. 28 is a perspective view illustrating an induction heater according to example embodiments;

FIG. 29 is a perspective view illustrating an induction heater according to example embodiments;

FIG. 30 is a cross-sectional view illustrating a semiconductor package according to example embodiments;

FIG. 31 is cross-sectional views illustrating a semiconductor package according to example embodiments;

FIGS. 32 through 36 are cross-sectional views illustrating a method for fabricating a semiconductor package according to example embodiments;

FIG. 37 is a block diagram illustrating a memory card including a semiconductor package and/or semiconductor module according to example embodiments; and

FIG. 38 is a block diagram illustrating a system including a semiconductor package and/or a semiconductor module according to example embodiments.

### DETAILED DESCRIPTION

Example embodiments will be described below in more detail with reference to the accompanying drawings. Example embodiments may, however, be embodied in different forms and should not be construed as limited to example embodiments set forth herein. Rather, example embodiments are provided so that this disclosure will be thorough and complete. In the figures, the dimensions of elements may be exaggerated for clarity of illustration.

It will be understood that although the terms first and second are used herein to describe various elements, these elements should not be limited by these terms. These terms are only used to distinguish one element from another element.

The advantages, features and aspects of example embodiments will become apparent from the following description with reference to the accompanying drawings, which is set forth hereinafter. Example embodiments may, however, be embodied in different forms and should not be construed as limited to the embodiments set forth herein. Rather, these embodiments are provided so that this disclosure will be thorough and complete, and will fully convey the scope of the present invention to those skilled in the art. The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless defined as other meanings, all terms including technical or scientific terms, which are used herein, have the same meanings as those that are commonly understood to those skilled in the art. Terms identical to predefined terms, which are generally used, should be interpreted to have meanings according with those in the context of relevant technology, and unless defined clearly in embodiments of the inventive concept, should not ideally or excessively be interpreted as formal meanings.

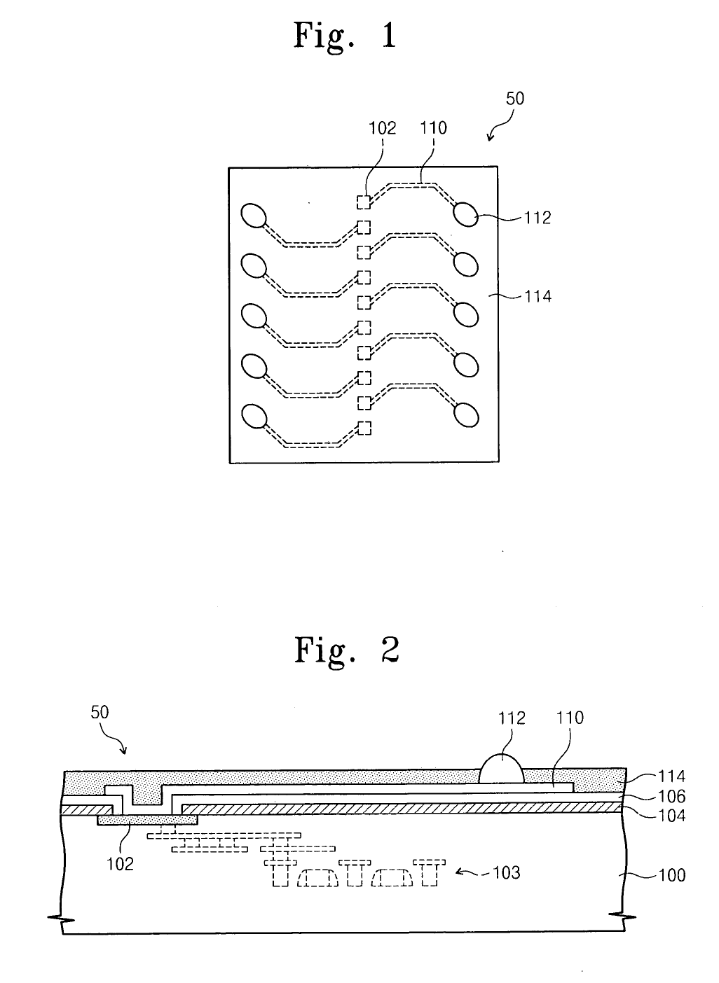

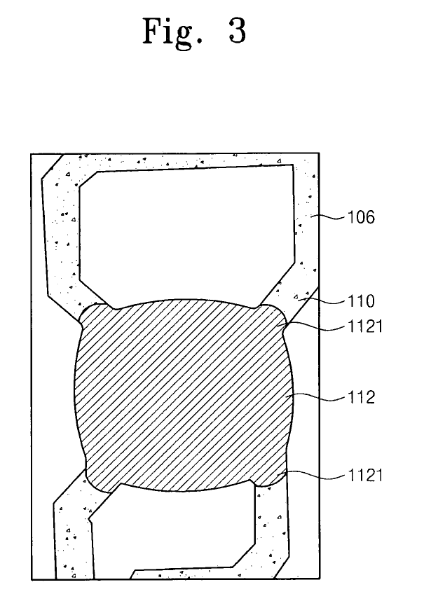

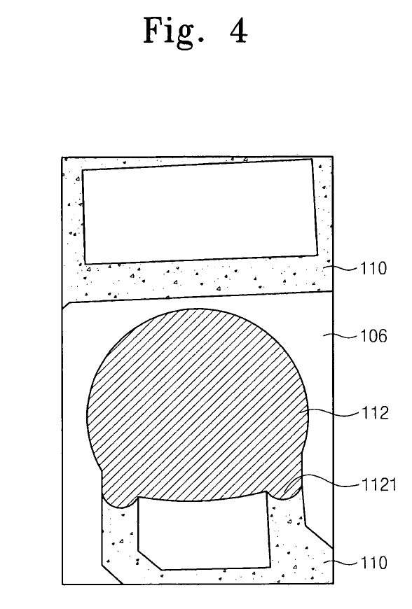

FIG. 1 is a plan view illustrating a semiconductor package according to example embodiments. FIG. 2 is a cross-sectional view illustrating a portion of the semiconductor package in FIG. 1. FIGS. 3 and 4 are plan views magnifying a portion of the semiconductor package in FIG. 1.

Referring to FIGS. 1 and 2, a semiconductor package 50 may include a substrate 100 including at least one bonding pad 102. For example, the substrate 100 may include an integrated circuit 103 that is formed on a wafer. As an example, the integrated circuit 103 may include a memory circuit, a logic circuit or the coupled circuit thereof. The wafer may be a semiconductor wafer including silicon (Si), germanium (Ge) or a silicon germanium (SiGe) or a Silicon On Insulator (SOI) wafer including an insulator at the inside. As another example, the substrate 100 may be the silicon wafer or SOI wafer of a chip level.

The bonding pad 102 may be electrically connected to the integrated circuit 103 at the substrate 100. The number of bonding pads 102 may be appropriately selected according to the kind and capacity of the integrated circuit 103, and it is not limited thereto. For example, the bonding pad 102 may be disposed at the substrate 100, and at least an upper surface of the bonding pad 102 may be exposed from the substrate 100. As another example, the bonding pad 102 may protrude from the surface of the substrate 100 or may be recessed inward.

In example embodiments, the bonding pad 102 may have a center pad structure which may be disposed near the surface center of the substrate 100, but example embodiments are not limited thereto. The bonding pad 102 may include a conductor, for example, aluminum (Al) or copper (Cu).

A passivation layer 104 may be disposed on the substrate 100 and may expose at least one portion of the bonding pad 102. The passivation layer 104 may include an insulator. An interlayer dielectric 106 may be disposed on the passivation layer 104 and may expose at least one portion of the bonding pad 102. For example, the interlayer dielectric 106 may be a polymer material, for example, a photosensitive material. In example embodiments, the passivation layer 104 and the interlayer dielectric 106 are categorized, but they may be referred to as one term without being categorized, or one of the passivation layer 104 and the interlayer dielectric 106 may be omitted.

At least one redistribution line 110 may extend from the bonding pad 102 and across the interlayer dielectric 106. For example, one end of the redistribution line 110 may directly contact the bonding pad 102. The redistribution line 102 may serve as an element for redistributing the bonding pad 102. In example embodiments, the redistribution line 110 may serve as an element that redistributes the bonding pad 102 of the center pad structure near the edge of the substrate 100, but it is not limited thereto. For example, the redistribution line 110 may adjust the distances between the bonding pads 102 or may be used to adjust distances and dispositions.

At least one external terminal 112 may be connected onto the redistribution line 110. Accordingly, the external terminal 112 may be connected to the bonding pad 102 through the redistribution line 110. The external terminal 112 may directly contact the redistribution line 110. A molding layer 114 covers and protects the redistribution line 110, and can protect the surface of the substrate 100 from an external environment.

Referring to FIGS. 3 and 4, the external terminal 112 may include at least one protrusion 1121. The protrusion 1121 may increase the bonding strength between the external terminal 112 and the redistribution line 110. For example, a plurality of redistribution lines 110 may be connected to one external terminal 112, and a plurality of protrusions 1121 may be disposed to protrude along the redistribution lines 110. The redistribution line 110 may have a bent shape, and the protrusion 1121 may be limited in the bent line of the redistribution line 110 that may be near to the external terminal 112. The width of the bent line may be narrower relative to the size of the external terminal 112. Accordingly, because the width of the protrusion 1121 is limited within the narrow bent line, the excessive enlargement of the protrusion 1121 may be prevented or reduced.

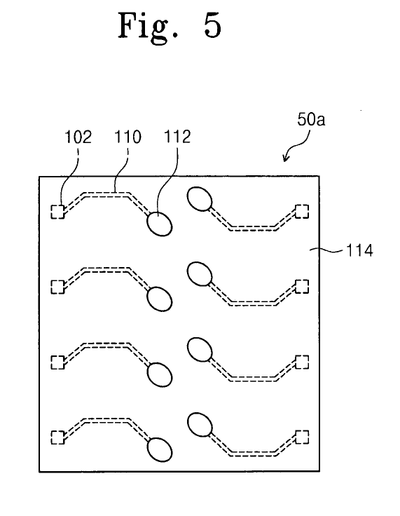

FIG. 5 is a perspective view illustrating a semiconductor package according to example embodiments. The semiconductor package example embodiments may refer to the semiconductor package 50 in FIGS. 1 through 4, and thus repetitive description will be omitted.

Referring to FIG. 5, a semiconductor package 50a may have an edge pad structure in which a bonding pad 102 is disposed near an edge of a substrate 100. An external terminal 112 may be connected to the bonding pad 102 through a redistribution line 110, and may be disposed near the center of the substrate 100. However, example embodiments are not limited to such a disposition. The disposition of the bonding pad 102, the redistribution line 110 and the external terminal 112 may be appropriately modified.

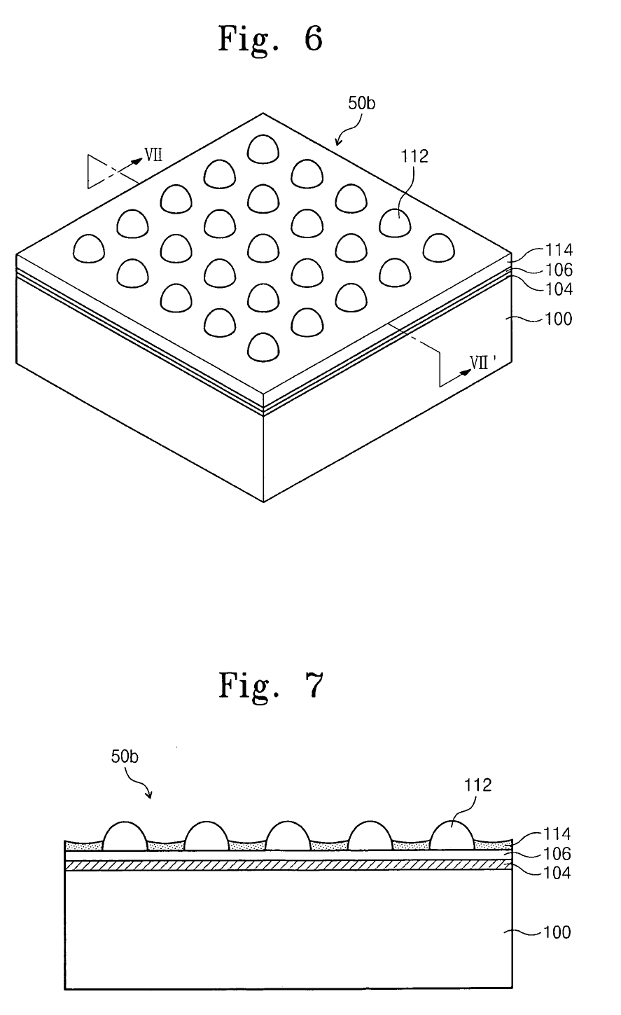

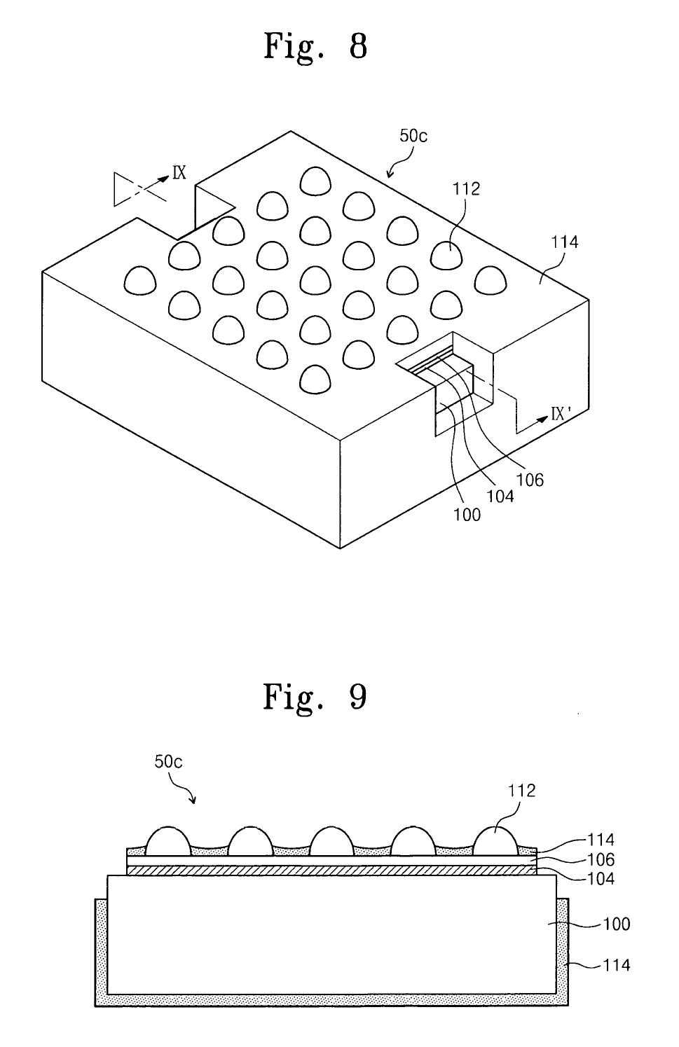

FIG. 6 is a perspective view illustrating a semiconductor package according to example embodiments. FIG. 7 is a cross-sectional view taken alone line VII-VII′ in the semiconductor package in FIG. 6. The semiconductor package according to example embodiments may refer to the semiconductor package 50 in FIGS. 1 through 4, and thus repetitive description will be omitted. For simplification of illustration, the bonding pad 102 and the redistribution line 110 in FIGS. 1 through 4 are omitted in FIGS. 6 and 7.

Referring to FIGS. 6 and 7, a semiconductor package 50b may have a structure in which external terminals 112 are arranged in a matrix on the substrate 100. However, such arrangement is exemplarily illustrated, and example embodiments are not limited thereto. For example, the external terminals 112 may also be arranged, like in FIG. 1 or FIG. 5.

A molding layer 114 may be disposed to expose a portion of each external terminal 112. The molding layer 114, for example, may be between the external terminals 112. For example, the molding layer 114 may be disposed to be concaved in the direction of the substrate 100 between two adjacent external terminals 112. The molding layer 114 may include a dielectric resin material, for example, an Epoxy Molding Compound (EMC).

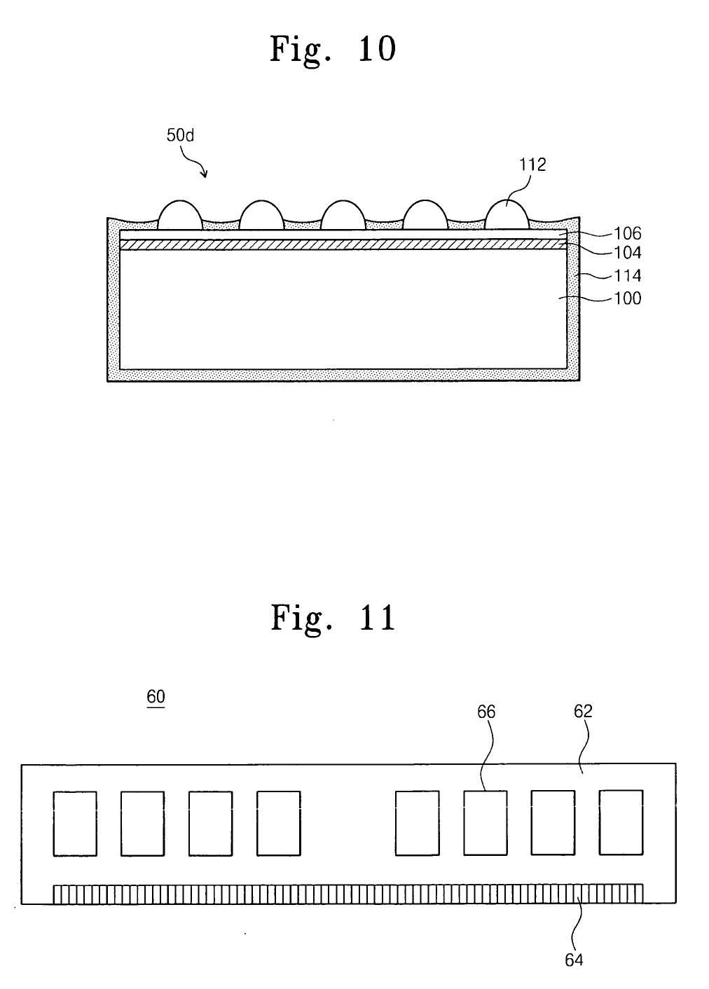

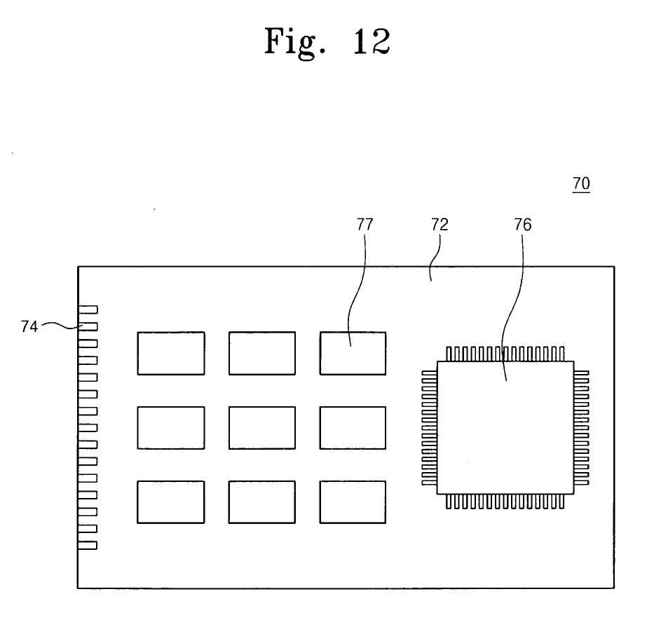

FIG. 8 is a perspective view illustrating a semiconductor package according to example embodiments. FIG. 9 is a cross-sectional view taken alone line IX-IX′ in the semiconductor package in FIG. 8. The semiconductor package according to example embodiments may refer to the semiconductor package 50b in FIGS. 6 and 7, and thus repetitive description will be omitted.

Referring to FIGS. 8 and 9, a semiconductor package 50c may have a structure in which a molding layer 114 covers a first surface (for example, a front surface), a second surface opposite to the first surface (for example, a second surface), and side surfaces of a substrate 100 that include a bonding pad 102. For example, the molding layer 114 may cover all the surfaces of the substrate 100, and may expose a portion of each external terminal 112 and/or a portion of at least one edge or corner of the substrate 100. This structure may be formed by forming the molding layer 114 with a mold, and may be useful in a case where the molding layer 114 is formed on one substrate 100, a plurality of substrates 100, a plurality of semiconductor chips or a plurality of semiconductor chips formed on one wafer at one time.

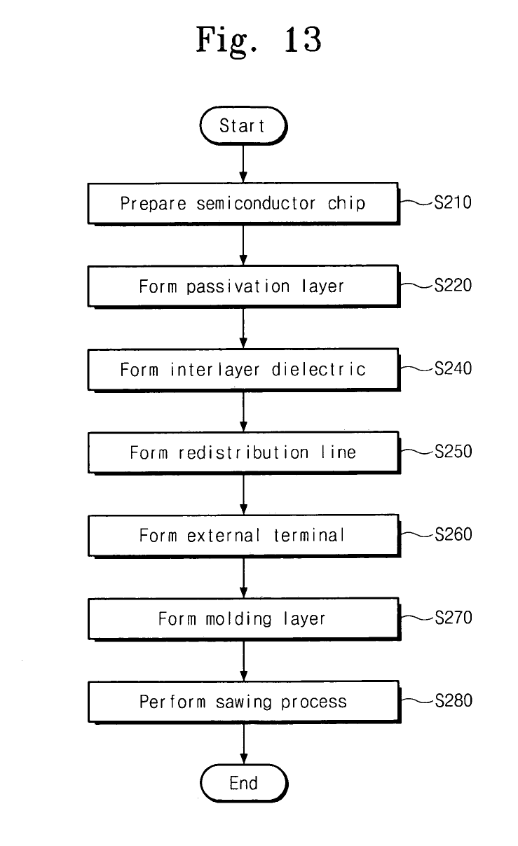

FIG. 10 is a perspective view illustrating a semiconductor package according to example embodiments. The semiconductor package according to example embodiments may refer to the semiconductor package 50c in FIG. 9, and thus repetitive description will be omitted.

Referring to FIG. 10, a semiconductor package 50d may have a structure in which a molding layer 114 surrounds all the surfaces of a substrate 100 and exposes a portion of each external terminal 112.

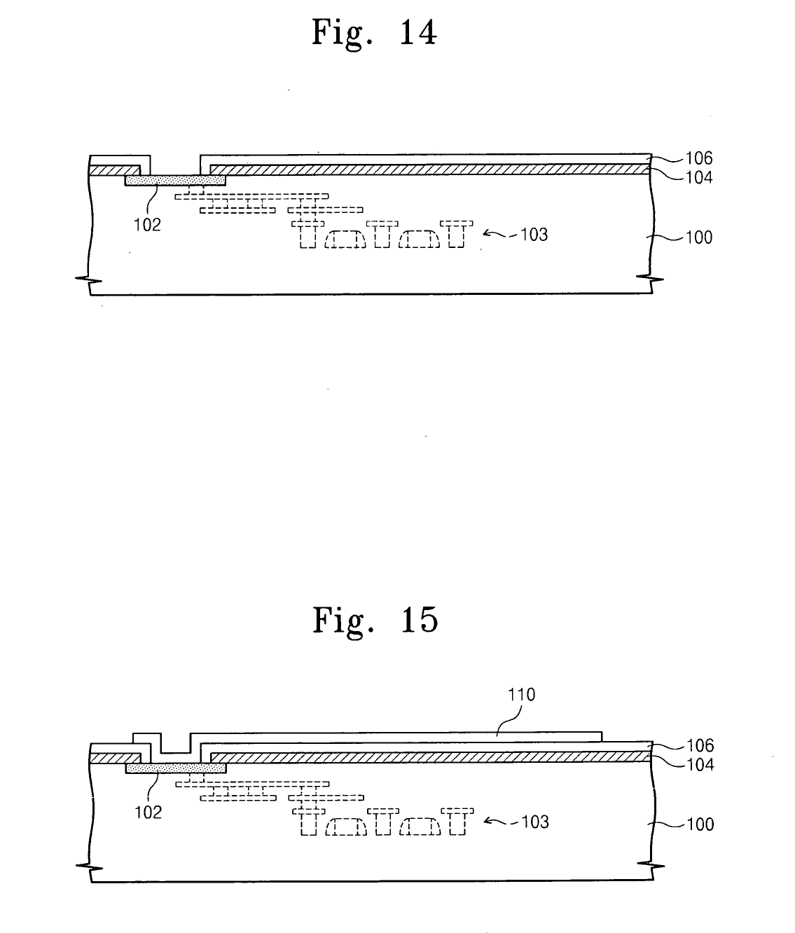

FIG. 11 is a plan view illustrating a semiconductor module according to example embodiments.

Referring to FIG. 11, a semiconductor module 60 may have a structure in which a plurality of semiconductor packages 66 are mounted on a module substrate 62. The module substrate 62 may include external connection terminals 64 for connecting with an electronic device. For example, the module substrate 62 may include a printed circuit board, and the external connection terminals 64 may include connection pins.

Semiconductor packages 66 may correspond to the semiconductor packages 50 through 50d in FIGS. 1 and 10. The semiconductor packages 66 may be electrically connected to the module substrate 62 through the external terminals 112 in FIGS. 1 through 10. For example, in a case where memory chips are mounted on the semiconductor packages 66, the semiconductor module 60 may be used as a memory module. The memory chips may include various memory devices, for example, DRAM devices, SRAM devices, FLASH devices, PRAM devices, RRAM devices, MRAM devices and FRAM devices.

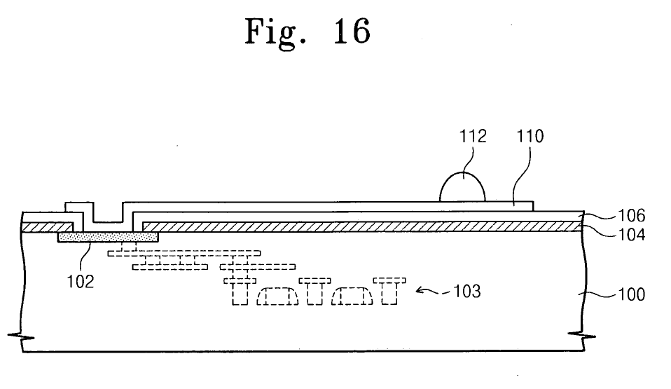

FIG. 12 is a plan view illustrating a semiconductor module according to example embodiments.

Referring to FIG. 12, a semiconductor module 70 may have a structure in which a semiconductor chip 77 and a Quad Flat Package (QFP) type of semiconductor package 76 are mounted on a module substrate 72. The semiconductor package 76 may be one in which at least one or two of the semiconductor packages 50 through 50d are combined. The semiconductor module 70 may be electrically connected to an external device through a plurality of external connection terminals 74 included in the one side of the module substrate 72.

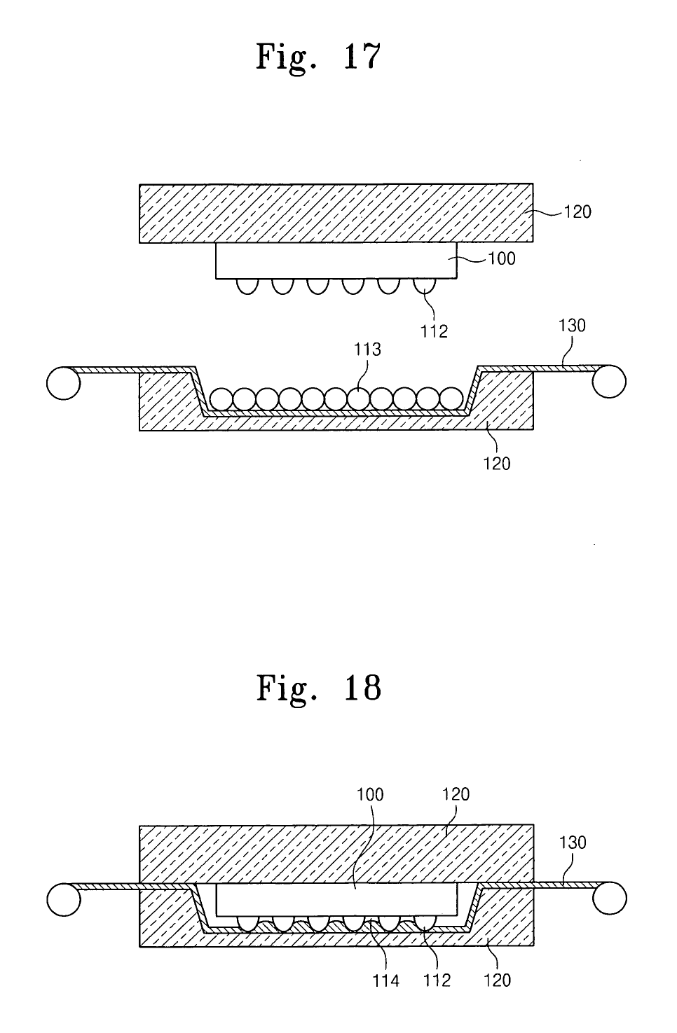

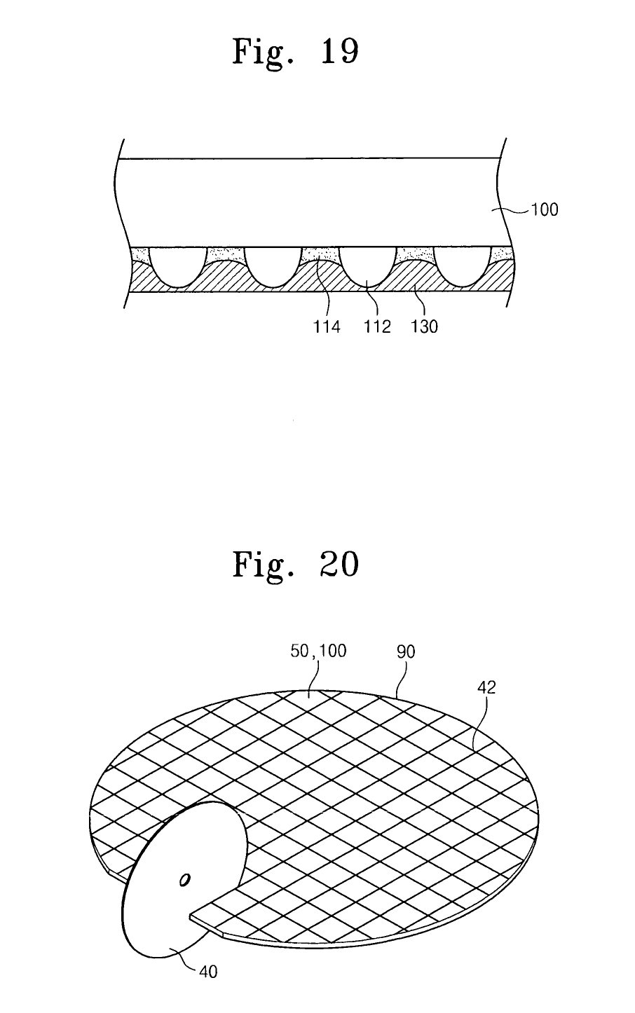

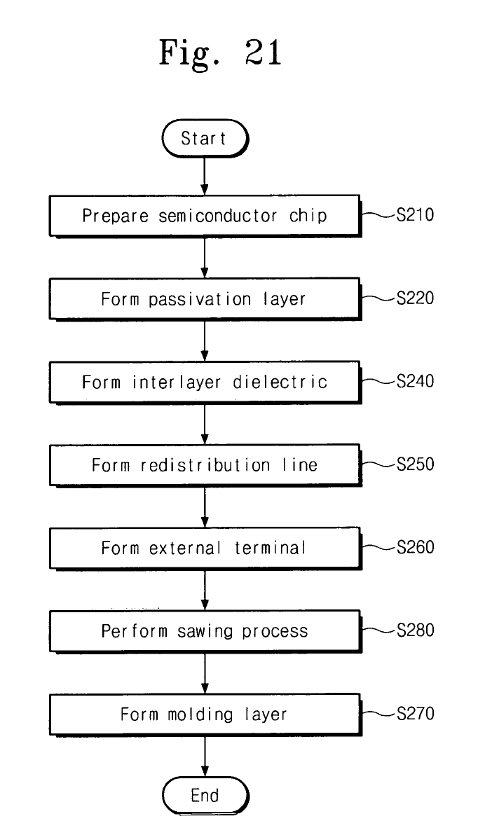

FIG. 13 is a flowchart illustrating a method for fabricating a semiconductor package according to example embodiments. FIGS. 14 through 19 are cross-sectional views illustrating a method for fabricating a semiconductor package according to example embodiments. FIG. 20 is a perspective view illustrating a method for fabricating a semiconductor package according to example embodiments.

Referring to FIGS. 13 and 14, at least one substrate 100 including at least one bonding pad 102 may be provided (S210). The substrate 100 may be a semiconductor chip in which an integrated circuit 103 is formed on a wafer. For example, as illustrated in FIG. 20, the substrate 100 may be provided as one die on a semiconductor wafer 90. The number of substrates 100 may be adjusted according to the size of the semiconductor wafer 90, and example embodiments are not limited thereto. The bonding pad 102 may include Al or Cu.

A passivation layer 104 exposing a portion of the bonding pad 102 may be formed on the substrate 100 (S220). For example, the passivation layer 104 may be formed by forming a dielectric layer and patterning it. In example embodiments, in a state where the passivation layer 104 has been formed, the substrate 100 may be conveyed for an assembly process.

An assembly stage may be performed. For example, an interlayer dielectric 106 for exposing a portion of the bonding pad 102 may be formed on the passivation layer 104 (S240). For example, the interlayer dielectric 106 may be formed by forming a photosensitive polymer material, for example, a polyimide layer on the passivation layer 104 and patterning it. The photosensitive polymer material may be formed in a spin coating process or a deposition process.

Referring to FIGS. 13 and 15, at least one redistribution line 110 may be formed to extend from the bonding pad 102 to the interlayer dielectric 106 (S250). For example, by forming a conductive layer on the bonding pad 102 and the interlayer dielectric 106 and patterning it, the redistribution line 110 may be formed. As an example, the redistribution line 110 may be formed of Al or W.

As another example, a seed layer may be formed and patterned on the bonding pad 102 and the interlayer dielectric 106. The redistribution line 110 may be formed by forming a plating layer on the seed layer. For example, the seed layer and the plating layer may include Cu.

Referring to FIGS. 13 and 16, at least one external terminal 112 may be formed on the redistribution line 110 (S260). The external terminal 112 may be formed with a solder ball. For example, solder may be formed on the redistribution line 110 in a screen printing process, and by melting the solder in a reflow process, a solder ball may be formed. The reflow process may be performed at about 200 to 250 degrees centigrade.

The melted solder is spread by liquefied properties. Spreading may be stopped by the redistribution line 110 and surface tension, and thus a waterdrop type of solder may be kept. The waterdrop type of solder may be cooled, thereby forming the solder ball. The solder ball may have an oval cross-sectional surface. Accordingly, the external terminal 112 may have a structure which protrudes along the redistribution line 110. For example, as illustrated in FIG. 3 or FIG. 4, the external terminal 112 may include the protrusions 1121.

In a case of using such a method for forming the external terminal 112, a second interlayer dielectric (not shown) for forming the external terminal 112 on the redistribution line 110 is not required. To keep the shape of the external terminal 112, the second interlayer dielectric (e.g., a solder mask) having a pattern shape in which the external terminal 112 may be formed may be required on the redistribution line 110. However, in example embodiments, the forming and patterning stages of the second interlayer dielectric may be omitted.

Referring to FIGS. 13 and 17, a molding layer 114 may be formed on the substrate 100 to expose a portion of the external terminal 112 (S270). For example, as illustrated in FIG. 17, a sacrificial layer 130 may be disposed in molds 120, and molding members 113 may be disposed on the sacrificial layer 130. The substrate 100 may be disposed in the molds 120 for the external terminal 112 to face the molding members 113. For example, the sacrificial layer 130 may use a flexible film.

Referring to FIGS. 18 and 19, a molding layer 114 may be formed between the external terminals 112 by compressing the molds 120. As depicted in FIG. 17, the molding members 113 are compressed by the sacrificial layer 130 and are penetrated between the external terminals 112, thereby forming the molding layer 114. In example embodiments, because of the flexibility of the sacrificial layer 130, the molding layer 114 may be formed in a concave shape in the direction of the substrate 100 between the external terminals 112. Moreover, the molding layer 114 is not penetrated into the contact portion between the sacrificial layer 130 and the external terminal 112, and therefore the upper portion of the external terminal 112 may be exposed to form the molding layer 114. The molding layer 114 may be hardened by thermal treatment.

Referring to FIGS. 13 and 20, by cutting the semiconductor wafer 90, the semiconductor package 50 may be separated from the semiconductor wafer 90 (S280). For example, the semiconductor packages 50 may be simultaneously formed on the semiconductor wafer 90, and the semiconductor packages 50 may be separated from each other in a sawing process. The sawing process may include separating along a scribe lane 42 with a cutting wheel 40 or a laser.

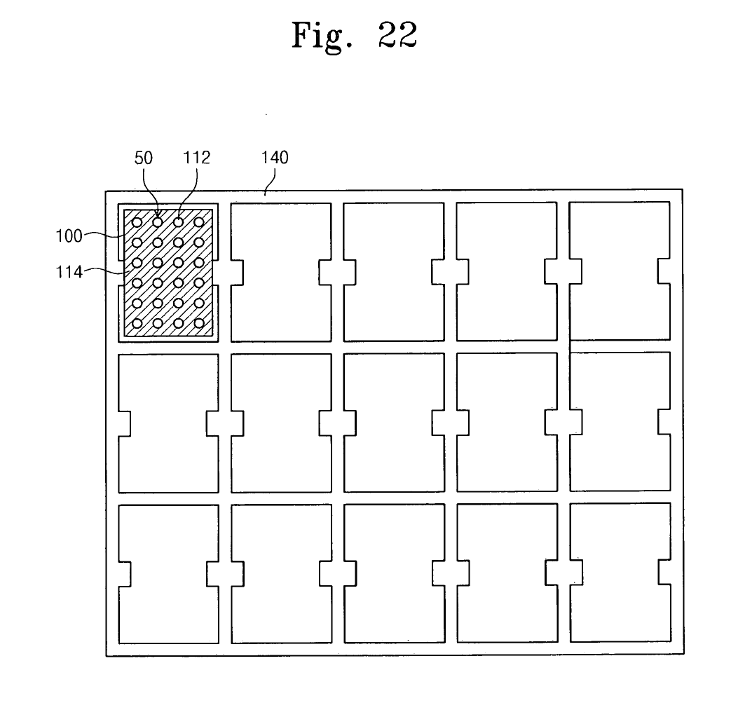

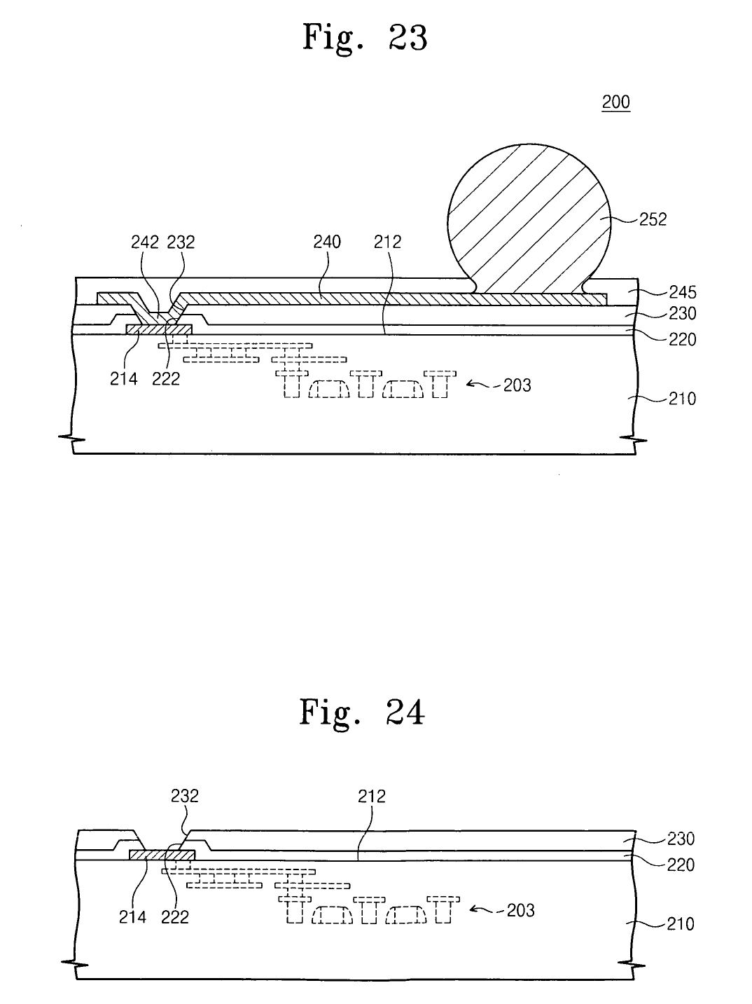

FIG. 21 is a flowchart illustrating a method for fabricating a semiconductor package according to example embodiments. FIG. 22 is a plan view illustrating a method for fabricating a semiconductor package according to example embodiments. The fabrication method according to example embodiments may refer to the fabrication method in FIGS. 13 through 20, and thus repetitive description will be omitted.

Referring to FIGS. 21 and 22, operations of providing the substrate 100 (S210) through an operation of forming the external terminal 112 (S260) may be similar to the operations illustrated in FIGS. 13 through 16. A sawing process (S280) may be performed and an operation of forming the molding layer 114 (S270) may be successive. In example embodiments, the sawing process (S280) and the operation of forming the molding layer 114 (S270) may be contrary to FIG. 13. In the sawing process (S280), the substrate 100 may be separated from the semiconductor wafer 90 in FIG. 20.

The substrate 100 may be disposed in a molding frame 140, and the molding layer 114 may be formed to substantially surround all the surfaces of the substrate 100 while exposing a portion of the external terminal 112 (S270). For example, when forming the molding layer 114, the sacrificial layer 130 in FIGS. 17 and 18 may be used for exposing the external terminal 112.

In example embodiments, the molding layer 114 may be formed on all the surfaces of the substrate 100, and the external terminal 112 may be exposed from the molding layer 114 in a grinding process. Because, the substrate 100 may be fixed inside the molding frame 140 to surround all the surfaces, as illustrated in FIG. 8, the molding layer 114 may not exist in an edge portion contacting the molding frame 140. Such a structure may be relatively robust and resistive to external stress because the molding layer 114 may surround all the substantial surfaces of the substrate 100.

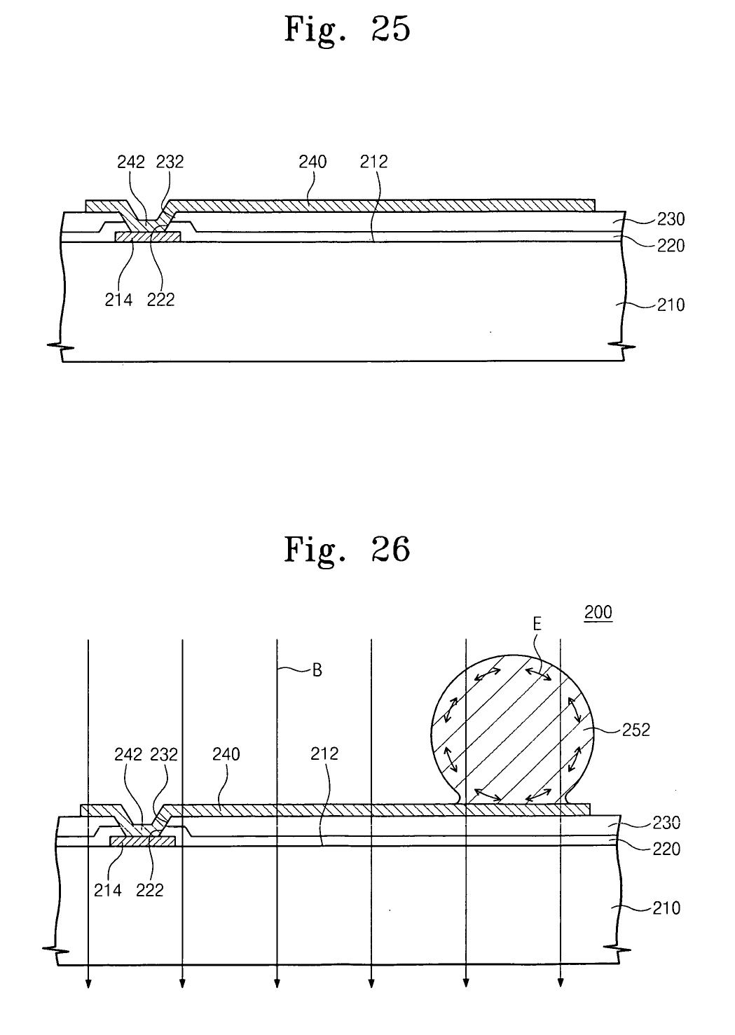

FIG. 23 is a cross-sectional view illustrating a semiconductor package according to example embodiments.

Referring to FIG. 23, a semiconductor package 200 may include a substrate 210, a passivation layer 220, an interlayer dielectric 230, and a redistribution line 240. The substrate 210 has an upper surface 212 in which at least one bonding pad 214 may be formed. The passivation layer 220, the interlayer dielectric 230 and the redistribution line 240 may be sequentially stacked on the upper surface 212. The upper surface 212 may be an active surface. The semiconductor package 200 may further include a molding layer 245 that may cover the redistribution line 240 and protect the substrate 210.

The substrate 210 may be one for fabricating an electrical device. For example, the substrate 210 may be the semiconductor (for example, Si) substrate or SOI substrate of a wafer level, which includes an integrated circuit 203. As another example, the substrate 210 may be the silicon or SOI wafer of a chip level.

The passivation layer 220 may be formed to cover the upper surface 212 while exposing the bonding pad 214. The passivation layer 220 may have a first opening 222 for exposing the bonding pad 214.

The interlayer dielectric 230 may be formed to cover the passivation layer 220 and expose the bonding pad 214. The interlayer dielectric 230 may have a second opening 232 for exposing the first opening 232.

The redistribution line 240 may be disposed on the interlayer dielectric 230. A portion 242 of the redistribution line 240 may be directly and electrically connected to the bonding pad 214 through the first and second openings 222 and 232. At least one external terminal 252 may be disposed on the redistribution line 240. Accordingly, the redistribution line 240 may electrically connect the bonding pad 214 and the external terminal 252. The external terminal 252 may directly join a solder ball on the redistribution line 240 and be thereby formed. The external terminal 252 may be a solder ball for electrically connecting an external device (not shown) to an integrated circuit 203 included in the substrate 210. As described above, the semiconductor package 200 may include the redistribution line 240 and the external terminal 252 that is directly joined to the redistribution line 240. Therefore, the semiconductor package 200 need not form the external terminal 252, for example, a second interlayer dielectric (e.g., a solder mask) defining a ball land that limits the disposition region of a solder ball. Accordingly, example embodiments may provide the semiconductor package 200 having a simple structure.

The following description will be made in detail on a semiconductor package according to example embodiments. Repetitive description will be omitted or simplified on the semiconductor device 200.

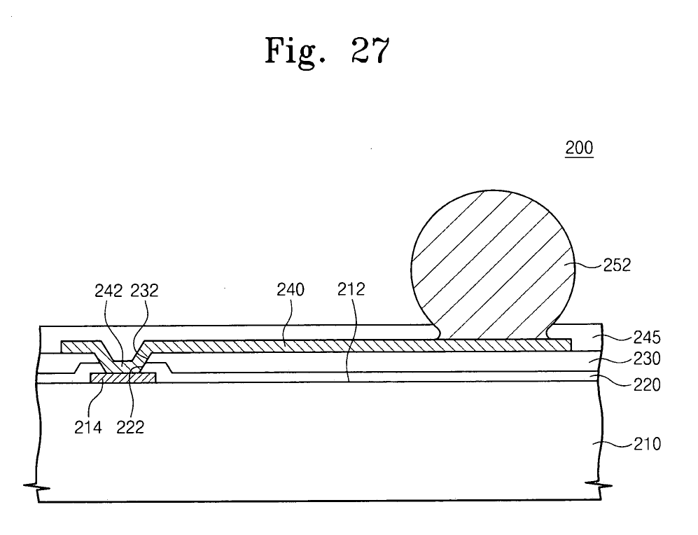

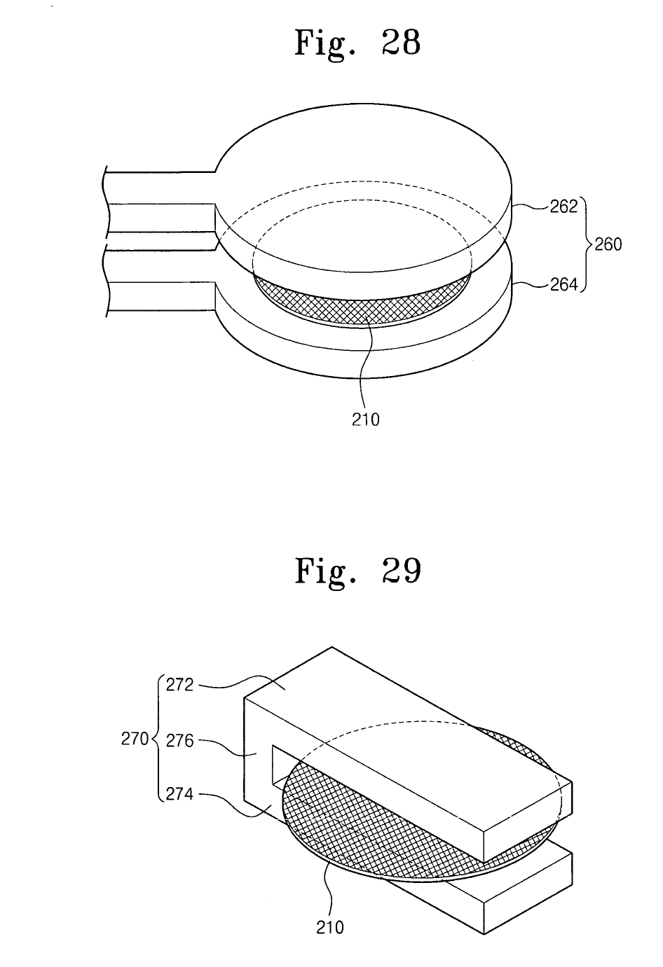

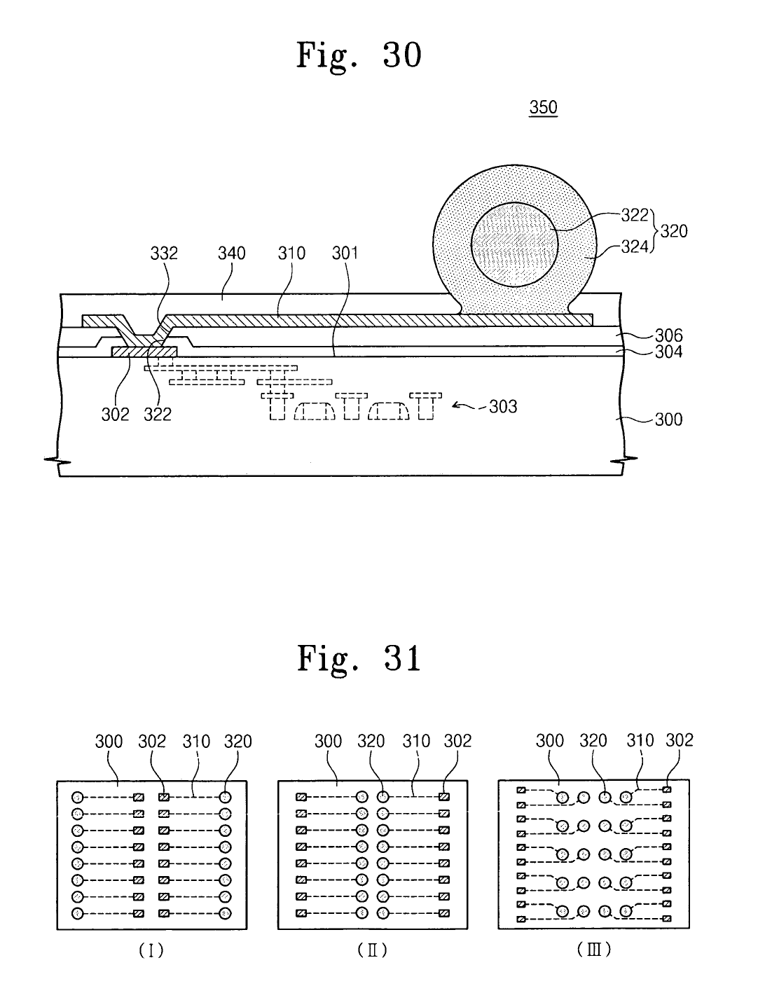

FIGS. 24 through 27 are cross-sectional views illustrating a method for fabricating the semiconductor device in FIG. 23. FIGS. 28 and 29 are perspective views illustrating induction heaters according to example embodiments.

Referring to FIG. 24, a substrate 210 may be prepared. The substrate 210 may be a wafer in which an integrated circuit 203 is formed or a semiconductor substrate of a chip level, for example, silicon or SOI wafer. The substrate 210 may have an upper surface 212 in which a bonding pad 214 is formed.

A passivation layer 220 and an interlayer dielectric 230 may be formed on the upper surface 212. Forming the passivation layer 220 may include forming a dielectric layer covering the entirety of the upper surface 212. Forming the interlayer dielectric 230 may include forming a dielectric layer covering the front surface of the passivation layer 220, for example, an oxide layer, nitride layer or a resin layer. A process of forming first and second openings 222 and 232 for exposing the bonding pad 214 may be performed. The process of forming the first and second openings 222 and 232 may include patterning the interlayer dielectric 230 and the passivation layer 220 to form a trench for exposing the bonding pad 214.

Referring to FIG. 25, a redistribution line 240 may be electrically connected to the bonding pad 214 of a substrate 210 and may be formed on the interlayer dielectric 230. For example, forming the redistribution line 240 may include forming a metal layer covering the bonding pad 214 and the interlayer dielectric 230, and then patterning the metal layer. The bonding pad 214 may be directly connected through a first opening 222 formed in a passivation layer 220 and second openings 232 formed in the interlayer dielectric 230. The redistribution line 240 may be directly connected to an integrated circuit 203 included in the substrate 210.

Referring to FIG. 26, an external terminal 252 may be formed. The external terminal 252 may be directly formed on a redistribution line 240. The redistribution line 240 may be disposed on the substrate 210, and may be connected to the bonding pad 214 through the first and second openings 222 and 232. The passivation layer 220 and the interlayer dielectric 230 may be interposed between the redistribution line 220 and the substrate 210. The external terminal 252 may be electrically connected to the integrated circuit (203 in FIG. 23) included in the substrate 210.

Forming the external terminal 252 may include disposing a solder ball on the redistribution line 240, and heating the solder ball. At this point, the solder ball may not have a sphere. The external terminal 252 may be directly joined onto the redistribution line 240. Forming the external terminal 252 may further include coating a flux (not shown) on the redistribution line 240 before disposing the solder ball. The flux may include a material including any one of a resin, a thinner and an activator.

Forming the external terminal 252 may further include providing a magnetic field B to the solder ball that may be disposed on the redistribution line 240. The magnetic field B may allow the solder ball to be joined onto the redistribution line 240 while forming a sphere by reflowing. For example, in a process of heating the solder ball disposed on the redistribution line 240, an electric field E may be produced in the outer portion of the solder ball when providing the magnetic field B to the solder ball. The magnetic field B may include an Alternating Current (AC) magnetic field. The electric field E may allow thermal treatment to be selectively performed in the outer portion of the solder ball and thereby may enable the external terminal 252 to be joined onto the redistribution line 240 while forming a sphere.

Heating the solder ball may be performed with a heater. Referring to FIG. 28, as an example, heating the solder ball may include heating the solder ball with an induction heater 260 having a circular plate shape. For example, the induction heater 260 may include a circular plate shape of first heater 262 which is disposed over the substrate 210, and a circular plate shape of second heater 264 which is disposed under the substrate 210. The first and second heaters 262 and 264 may be disposed parallel to the substrate 210. The second heater 264 may be used as a supporter for supporting the substrate 210. At least one of the first and second heaters 262 and 264 may include a coil that produces heat by a high-frequency induced current or a low-frequency induced current. The size of the coil may be equal to or greater than the diameter of the substrate 210. The turn number of the coil may be one or greater. The induction heater 260 may be adjusted at a frequency of 10 MHz or higher and a power of 2000 Watt or higher.

Referring to FIG. 29, as another example, heating the solder ball may include heating the solder ball with the induction heater 270 having a rectangular shape. That is, the induction heater 270 may include a bar shape of first heater 272 which is disposed over the substrate 210, a bar shape of second heater 274 which is disposed under the substrate 210, and a connection portion 276 for connecting the first and second heaters 272 and 274. The first and second heaters 272 and 274 may be disposed parallel to the substrate 210, and the connection portion 276 may be disposed vertically to the substrate 210. The induction heaters 260 and 270 may include coils (not shown) that produce heat by a high-frequency induced current or a low-frequency induced current.

As described above, heating the solder ball may include heating the solder ball with one of the induction heaters 260 and 270 that have been adjusted at a frequency of 10 MHz or higher and a power of 2000 Watt or higher. Time taken when each of the induction heaters 260 and 270 heats the solder ball may be within five seconds. By heating the solder ball through the above-described conditions, the fabrication method prevents or reduces the solder ball from being excessively melted and thereby prevents or reduces its shape from being crumpled. The fabrication method may also prevent or reduce an area joined to the redistribution line 240 from being excessively enlarged.

In example embodiments, the semiconductor package 200 having the external terminal 252 satisfying a shape (for example, a sphere) that is directly predetermined or preset on the redistribution line 240 may be implemented with the induction heaters 260 and 270 and/or the magnetic field B. The semiconductor package 200 may skip forming a solder mask that defines a ball land for limiting the position of the external terminal 252 on the redistribution line 240. According to example embodiments, the structure of the semiconductor package 200 may be simplified, and the cost may be reduced or minimized.

Referring to FIG. 27, the molding layer 245 may be further formed. The molding layer 245 may protect the redistribution line 240, and may protect the semiconductor package 200 against an external environment. The molding layer 245 may be formed of a dielectric resin or an EMC. The molding layer 245 may be hardened by thermal treatment. The molding layer 245, as illustrated in FIGS. 17 and 18, may be formed using the molds 120, or as illustrated in FIG. 22, it may be formed using the molding frame 140.

As illustrated in FIG. 20, a sawing process may be further performed in which the semiconductor package 200 of a wafer level is divided into the semiconductor package of a chip level. The sawing process may be performed after or before the formation of the molding layer 245.

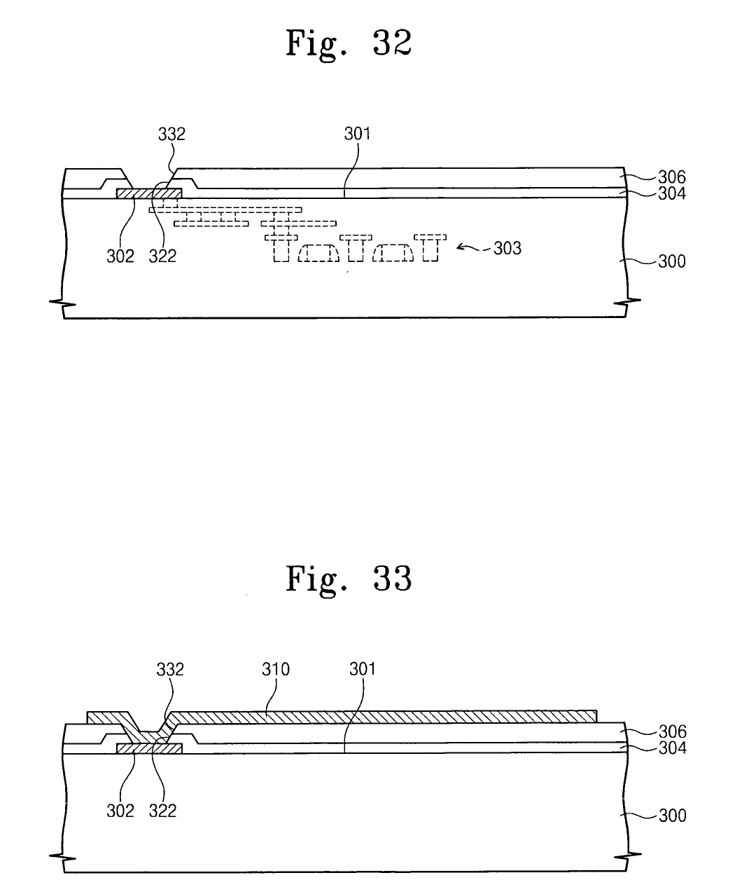

FIG. 30 is a cross-sectional view illustrating a semiconductor package according to example embodiments.

Referring to FIG. 30, a semiconductor package 350 may include a substrate 300 in which at least one bonding pad 302 is formed, a passivation layer 304, an interlayer dielectric 306, and a redistribution line 310. The passivation layer 304, the interlayer dielectric 306 and the redistribution line 310 are sequentially stacked on the upper surface 301 of the substrate 300. The semiconductor package 350 may further include a molding layer 340. At least one external terminal 320 may be disposed on the redistribution line 310. A plurality of redistribution lines 310 may be prepared.

The substrate 300 may be a substrate of a wafer level, and the semiconductor package 350 may be a Wafer-level Fabricated Package (WFP). However, example embodiments are not limited thereto. For example, the substrate 300 may be a substrate of a chip (e.g., die) level, and the semiconductor package 350 may be a Chip Scale Package (CSP). An integrated circuit 303 electrically connected to the bonding pad 302 may be formed in the substrate 300.

The number of bonding pads 302 may be suitably selected according to the kind and capacity of the integrated circuit 303. For example, the bonding pads 302 may be irregularly arranged on the upper surface 301 of the substrate 300. Differently, the bonding pads 302 may be regularly arranged in a localized or an overall structure. As an example, a substrate 300 of a chip level, the bonding pads 302 may form a center pad structure in which they are arranged in one row or more near or at the center of the substrate 300. As another example, the bonding pads 302 may form an edge pad structure in which they are arranged in one row or more near or at the edge of the substrate 300. As another example, the bonding pads 302 may be arranged in a matrix type where they are irregularly or regularly distributed over the entire region of the substrate 300.

The passivation layer 304 may have a first opening 322 exposing the bonding pad 302. The interlayer dielectric 306 may have a second opening 332 exposing the first opening 322. In example embodiments, the passivation layer 304 and the interlayer dielectric 306 are categorized, but they may be referred to as one term without being categorized, or one of the passivation layer 304 and the interlayer dielectric 306 may be omitted and be referred to as arbitrary term.

A redistribution line 310 may be disposed on the interlayer dielectric 306 and may be electrically connected to the bonding pad 302 through the first and second openings 322 and 332. Accordingly, the redistribution line 310 may electrically connect the bonding pad 302 and an external terminal 320. The external terminal 320 may be directly attached onto the redistribution line 310 without using a solder mask. The redistribution line 310 may serve as an element for redistributing the bonding pads 302.

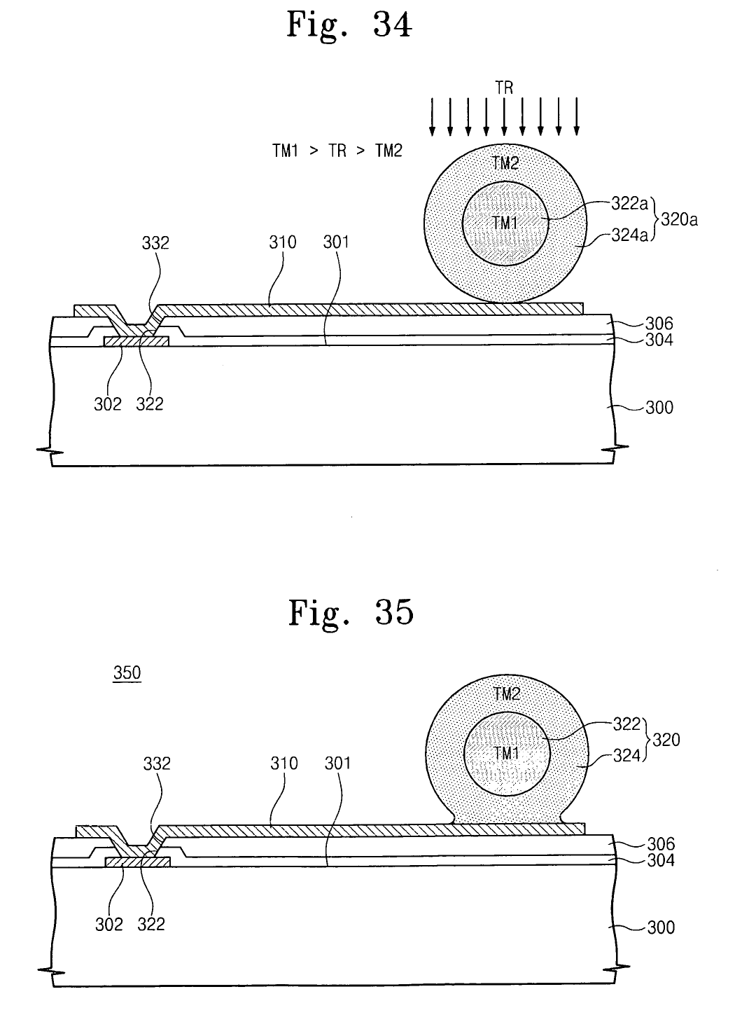

FIG. 31 are cross-sectional views illustrating a semiconductor package according to example embodiments. In FIG. 31, the substrate 300 is illustrated as a tetragonal shape of chip level substrate for convenience, and the passivation layer 304, the interlayer dielectric 306 and the molding layer 340 are omitted.

Referring to FIG. 31, as an example, redistribution lines 310 may redistribute the bonding pads 302 of a center pad structure to the edge of the substrate 300, in FIG. 31(I). In example embodiments, external terminals 320 may be arranged at the edge of the substrate 300. The bonding pads 302 may be arranged in one row or more near or at the center of the substrate 300. The external terminals 320 may be arranged in one row or more at the left and right edges or top, bottom, left and right edges of the substrate 300. As another example, the redistribution lines 310 may redistribute the bonding pads 302 of an edge pad structure to the center of the substrate 300, in FIG. 31(II). As another example, the redistribution lines 310 may redistribute the bonding pads 302 of the edge pad structure to a matrix type over the entire region of the substrate 300, in FIG. 31(III). The external terminals 320 may be arranged in a matrix type over the entire region of the substrate 300. In FIG. 31(III), the bonding pads 302 may have the center pad structure or may be arranged in a matrix type over the entire region of the substrate 300. As another example, the redistribution lines 310 may be used to adjust the distances between the bonding pads 302 and/or positions of the bonding pads 302. Example embodiments are not limited to the arrangement type of the bonding pads 302 and the external terminals 320 that have been described above with reference to FIG. 31.

Referring again to FIG. 30, the entirety of the external terminal 320 may be formed of the same material, or the inner portion and outer portion of the external terminal 320 may be formed of different materials. According to example embodiments, the external terminal 320 may correspond to the latter. As an example, the external terminal 320 may be a solder ball of a dual structure including an inner core 322 and an outer layer 324 surrounding the inner core 322. According to example embodiments, in a reflow process, the inner core 322 may be formed of a material that is not melted although the outer layer 324 is melted. The outer layer 324 may be formed of a relatively low melting point material, and the inner core 322 may be formed of a relatively high melting point material.

As described herein, a relatively high melting point and a relatively low melting point mean relative high and low melting points between the melting point of the inner core 322 and the melting point of the outer layer 324. For example, the inner core 322 may be configured with a relatively high melting point material, which means that the inner core 322 may be configured with a material having a melting point higher than that of the outer layer 324. Likewise, the outer layer 324 may be configured with a relatively low melting point material, which means that the outer layer 324 may be configured with a material having a melting point lower than that of the inner core 322.

Because the external terminal 320 is an electrical connection medium, the outer layer 324 may be configured with a conductive material. The inner core 322 may be configured with a conductive material, for example, a metal, or a nonconductive material, for example, a refractory resin. When the inner core 322 is configured with a conductive material, for example, a metal, the external terminal 320 may having superior electrical conductivity may be implemented. When the inner core 322 is configured with a refractory resin, for example, a polyimide, a lightening of the semiconductor package 350 may be achieved. The external terminal 320 may include a solder ball having a multi structure that may further include at least one of a conductive layer and a nonconductive layer.

The molding layer 340 may expose the external terminal 320 while covering the dielectric layer 306. As another example, the molding layer 340 may expose a portion of the external terminal 320 and be provided to mold the semiconductor package 350.

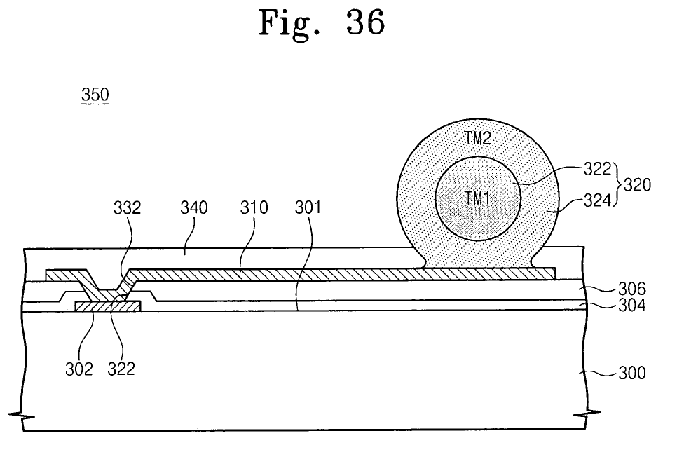

FIGS. 32 through 36 are cross-sectional views illustrating a method for fabricating a semiconductor package according to example embodiments.

Referring to FIG. 32, a substrate 300 may be provided. The substrate 300 may be a silicon (Si) substrate, silicon-germanium (SiGe) substrate or SOI substrate of a wafer level. As another example, the substrate 300 may be a chip (e.g., die) level substrate in which a wafer level substrate is sawed and individually separated. According to example embodiments, the substrate 300 may be a silicon substrate of a wafer level, however, example embodiments are not limited thereto. An integrated circuit 303 may be formed at the substrate 300. The integrated circuit 303 may be a memory circuit, a logic circuit, or a combined circuit thereof.

At least one bonding pad 302 electrically connected to the integrated circuit 303 may be formed at an upper surface 301 of the substrate 300. The bonding pads 302, as described above with reference to FIG. 31, may be formed in a center pad structure, an edge pad structure or a matrix structure. The bonding pad 302 may be formed of a conductive material including a metal, for example, Al, Cu, and/or an alloy thereof. The bonding pad 302 may be formed through the depositing and patterning or plating of a conductive material.

A passivation layer 304 having a first opening 322 exposing a portion of the bonding pad 302 may be formed at the upper surface 301 of the substrate 300. The passivation layer 304 may be formed through the depositing and patterning of an insulator. An interlayer dielectric 306 having a second opening 332, which may cover the passivation layer 304 and expose the first opening 322, may be formed. The bonding pad 302 may be exposed through the first and second openings 322 and 332. As another example, the passivation layer 304 and the interlayer 306 may be continuously formed through the depositing and patterning of an insulator, and the first and second openings 322 and 332 for exposing the bonding pad 302 may be formed. Forming the first and second openings 322 and 332 may include sequentially patterning the interlayer dielectric 306 and the passivation layer 304 to form a trench for exposing the bonding pad 302.

One of the passivation layer 304 and the interlayer dielectric 306 may be selectively omitted. In example embodiments, it will be described that the passivation layer 304 and the interlayer dielectric 306 is divided and formed, but example embodiments are not limited thereto. The passivation layer 304 and the interlayer dielectric 306 may be formed of the same material, or may be formed of different materials. For example, the passivation layer 304 may be formed by depositing an oxide or a nitride, and the interlayer dielectric 306 may be formed by depositing or spin coating a resin, for example, a polyimide, and the operations may be inversely performed.

Referring to FIG. 33, at least one redistribution line 310 may be formed on the interlayer dielectric 306. The redistribution line 310 may be formed though the depositing and patterning of a conductor, an electroless plating process, or an electroplating process. The redistribution line 310 may be formed of at least one metal, for example, Au, Ag, Pt, Cu, Al and W, and/or an alloy thereof. As an example, the redistribution line 310 may be formed by plating copper, and in which nickel may be thinly coated to prevent or reduce an oxidation of a copper surface. The redistribution line 310 may be electrically connected to the bonding pad 302 through the first and second openings 322 and 332. The redistribution line 310 may be formed in a straight-line type. Alternately, the redistribution line 310 may be formed in a bent type or several separated type.

Referring to FIG. 34, at least one solder ball 320a may be provided and attached to the redistribution line 310. Before selectively attaching the solder ball 320a, coating a flux on the redistribution line 310 may be further included. The flux may include any one of a resin, a thinner, and an activator.

The solder ball 320a may have a structure in which a non-melting material 322a and a melting material 324a are combined. As an example, the non-melting material 322a may have the shape of a solid sphere (hereinafter referred to as an inner core), and the melting material 324a may have the shape of a hollow sphere (hereinafter referred to as an outer layer) surrounding the non-melting material 322a. As another example, the melting material 324a may not be a sphere. According to example embodiments, the solder ball 320a may have a dual structure in which an outer layer 324a surrounds an inner core 322a. The melting point TM1 of the inner core 322a may be higher than the melting point TM2 of the outer layer 324a. As another example, the solder ball 320a may have a multi structure in which at least one intermediate layer surrounding the inner core 322a is further included between the inner core 322a and the outer layer 324a. The melting point of the intermediate layer may be equal to or higher than the melting point TM2 of the outer layer 324a. Alternatively, the melting point of the intermediate layer may be equal to or higher than the melting point TM1 of the inner core 322a. Alternatively, the melting point of the intermediate layer may be a value between the melting point TM2 of the outer layer 324a and the melting point TM1 of the inner core 322a.

The outer layer 324a may be formed of Pb, Pb/Sn, Sn/Zn, Sn/Bi, Sn/Ag, Sn/Zn/Bi. Sn/Ag/Cu, Sn/Bi/Ag/In, or the combination thereof.

The inner core 322a may be formed of a refractory metal, Cu, Ni or an alloy thereof. The refractory metal may include Mo, W, Ta, Nb, or the combination thereof. When the inner core 322a is configured with a conductor, the electrical conductivity of the external terminal (320 in FIG. 35) is improved. As another example, the inner core 322a may be configured with a refractory resin. The refractory resin may include polyamideimide, polyetherimide, polyethersulfone, polyarylate, polyphenylenesulfide, polyetheretherketone, polysulfone, or the combination thereof. When the inner core 322a is configured with the refractory resin, the lightening of the semiconductor package (350 in FIG. 350) may be achieved because the external terminal (320 in FIG. 35) is lightened.

In a state where the solder ball 320a is attached onto the redistribution line 310, a reflow process may be performed. A reflow temperature TR may be a value between the melting point TM1 of the inner core 322a and the melting point TM2 of the outer layer 324a. As an example, when the outer layer 324a is configured with Pb/Sn or Sn/Zn and the inner core 322a is configured with Ni, the reflow temperature TR may be a value in the temperature range of about 200 to 250 degrees centigrade, between the melting point TM2 (about 183 degrees centigrade) of Pb/Sn constituting the outer layer 324a and the melting point TM1 (about 1452 degrees centigrade) of Ni constituting the inner core 322a. When the solder ball 320a has a multi structure, the reflow temperature TR may be set so that the intermediate layer between the inner core 322a and the outer layer 324a may be melted together with the outer layer 324a or the intermediate layer and the inner core 322a may not be melted, when a reflow process is performed.

According to the reflow process, the outer layer 324a may be selectively melted, but the inner core 322a may keep an initial shape, for example, a sphere, without being melted. The outer layer 324a may be selectively melted thereby wetting at the redistribution line 310. The term “not infinitely wetted” means that the outer skin 324a is not wetted along the redistribution line 310 beyond an initially attached position of solder ball 320a during the reflow process. During the reflow process, the outer skin 324a may be partially melted but modified into a sphere by surface tension. Furthermore, the inner core 322a may keep an initial sphere shape without being melted during the reflow process, which may finitely wet the outer skin 324a on the redistribution line 310. However, in example embodiments, the outer layer 324a is not infinitely wetted along the redistribution line 310. Although the initial state of the outer layer 324a is not a sphere, the outer layer 324a may be melted in a reflow process and be modified into a sphere by surface tension. Accordingly, the melted solder ball 320a may keep a sphere shape at an attached position.

Referring to FIGS. 28 and 34, the solder ball 320a may be heated in a joule heating process using the induction heater 260, instead of the above-described convection reflow process. Time taken when the induction heater 260 heats the solder ball 320a may be shorter than the time taken in a general reflow process. As an example, if time taken in the convection reflow process is within about several minutes (for example, about 8 minutes), time taken in the joule heating process may be within several seconds (for example, within 5 seconds). Heating temperature may be limited in the convection reflow process, but when the joule heating process is applied, heating temperature may not be limited unlike the convection reflow process. According to example embodiments, if heating temperature is not limited, the inner core 322a may not be melted but the outer layer 324a may be selectively and quickly melted.

Referring to FIG. 35, at least one external terminal 320 may be formed on the redistribution line 310. The external terminal 320 may be formed by performing the reflowing or joule heating of the solder ball 320a having a dual structure that has been described above with reference to FIG. 34.

The solder ball 320a melted in the reflow process is wetted at the redistribution line 310. For limiting a wetted region to form the external terminal 320 having a desired shape at a desired position, by depositing a second interlayer dielectric on the interlayer dielectric 306 and performing a patterning process of opening a ball land region, a solder mask may be formed. Such a solder mask may serve as a guide that allows the solder ball 320a to be stably attached to the ball land, and suppresses a short between external terminals by preventing or reducing infinite wetting and protecting a redistribution line 310. In example embodiments a solder mask is not required because a molding process is subsequently performed, but the solder mask may be formed for defining a ball land and preventing or reducing infinite wetting. According to example embodiments, however, the external terminal 320 may be formed through the local melting of the solder ball 320a without forming a solder mask. According to a series of processes, the semiconductor package 350 of a wafer level may be implemented.

Referring to FIG. 36, the molding layer 340 may be selectively formed in a wafer level stage. The molding layer 340 may be formed to mold the upper surface 301 of the substrate 300. Alternatively, the molding layer 340 may be formed to mold the entirety of the semiconductor package 350. A portion of the external terminal 320 may be exposed from the surface of the molding layer 340. The molding layer 340 may be formed of a dielectric resin or an EMC. The molding layer 340 may be hardened through thermal treatment. The molding layer 340 may protect the redistribution line 310 and the semiconductor package 350 against an external environment. According to the wafer level molding process, the semiconductor package 350 having superior robustness may be implemented.

Referring to FIG. 20, a sawing process may be performed in which the semiconductor package 350 of a wafer level is divided into a chip scale semiconductor package in operation S380. In the chip scale semiconductor package, the external terminals 320 may be arranged at the edge of the substrate 300 as illustrated in FIG. 31(I), may be arranged at the center of the substrate 300 as illustrated in FIG. 31(II), or may be arranged in a matrix type as illustrated in FIG. 31(III).

As another example of a fabrication method, a process from a substrate providing stage to an external terminal forming stage may be performed similarly or identically to the process that has been described above with reference to FIGS. 32 through 35. Accordingly, as illustrated in FIG. 35, the semiconductor package 350 of a wafer level may be implemented. The fabrication method may include a sawing process so that a semiconductor package of a wafer level may be divided into a plurality of semiconductor packages of a wafer level. A molding layer 340 may be formed at a chip scale semiconductor package, unlike the wafer level molding process in FIG. 36.

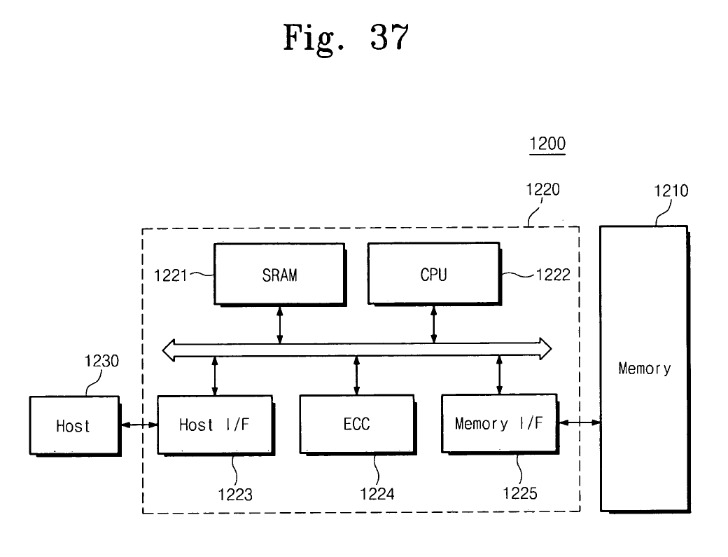

FIG. 37 is a block diagram illustrating a memory card including a semiconductor package and/or semiconductor module according to example embodiments.

Referring to FIG. 37, a semiconductor memory 1210 may include a semiconductor package and/or a semiconductor module according to example embodiments may be applied to a memory card 1200. As an example, the memory card 1200 may include a memory controller 1220 for controlling data exchange between a host 1230 and the memory 1210. A Static Random Access Memory (SRAM) 1221 may be used as the operation memory of a Center Processing Unit (CPU) 1222. A host interface 1223 may include the data exchange protocol of the host 1230 that may be connected to the memory card 1200. An Error Correction Code (ECC) 1224 may detect and correct the error of data that may be read from the memory 1210. The memory interface 1225 may interface with the memory 1210. The CPU 1222 may perform an overall control operation for the data exchange of the memory controller 1220.

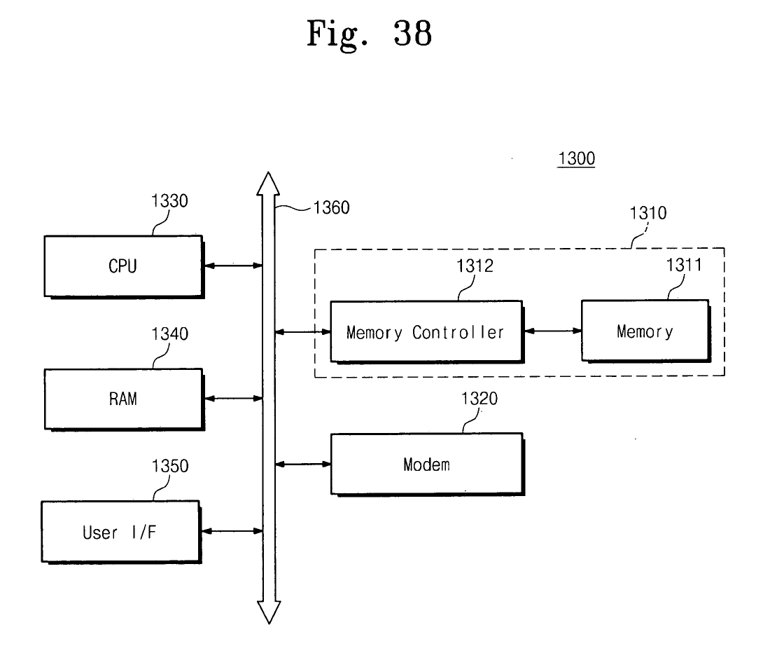

FIG. 38 is a block diagram illustrating an information processing system to which a semiconductor package and/or a semiconductor module according to example embodiments may be applied.

Referring to FIG. 38, an information processing system 1300 may include a memory system 1310 including a semiconductor package and/or a semiconductor module according to example embodiments. The information processing system 1300 may include a mobile device or a computer. As an example, the information processing system 1300 may include a modem 1320, a CPU 1330, a Random Access Memory (RAM) 1340 and a user interface 1350 which may be electrically connected to the memory system 1310 through a system bus 1360. The memory system 1310 may include a memory 1311 and a memory controller 1312, and may be configured to have the substantially same configuration as that of the memory card 1200 in FIG. 37. The memory system 1310 may store data processed by the CPU 1330 or data inputted from the outside. The information processing system 1300 may be provided as a memory card, a solid state disk (SSD), a camera image sensor and other application chipsets. As an example, the memory system 1310 may be configured with an SSD. In example embodiments, the information processing system 1300 can stably and reliably store large-scale data in the memory system 1310.

The semiconductor package according to example embodiments may be packaged in various types. For example, the semiconductor package according to example embodiments may be packaged in package types such as Package On Package (POP), Ball Grid Arrays (BGA), Chip Scale Packages (CSP), Plastic Leaded Chip Carrier (PLCC), Plastic Dual In-Line Package (PDIP), Die In Waffle Pack (DIWP), Die In Wafer Form (DIWF), Chip On Board (COB), Ceramic Dual In-Line Package (CERDIP), Plastic Metric Quad Flat Pack (MQFP), Thin Quad Flat Pack (TQFP), Small Outline Package (SOP), Shrink Small Outline Package (SSOP), Thin Small Outline Package (TSOP), Thin Quad Flat Pack (TQFP), System In Package (SIP), Multi Chip Package (MCP), Wafer-level Fabricated Package (WFP) and Wafer-Level Processed Stack Package (WSP), Wafer Level Stack Package (WLSP), Die In Wafer Form (DIWF), Die On Waffle Package (DOWP).

According to example embodiments, the reliability of the semiconductor package may be secured while omitting a process of forming the solder mask for forming the shapes of the external terminals on the redistribution line. Accordingly, the consumption of the insulator can decrease and a process time can be shortened. Moreover, because of omitting the patterning stage of the solder mask, a photolithography stage may be omitted. Therefore, a stage for forming the semiconductor package may be simplified thus reducing or saving the cost.

While example embodiments have been particularly shown and described with reference to example embodiments thereof, it will be understood by those of ordinary skill in the art that various changes in form and details may be made therein without departing from the spirit and scope of the following claims.

1. A method for fabricating semiconductor package, the method comprising:
providing a substrate comprising a bonding pad;
forming a dielectric layer to expose the bonding pad on the substrate;
forming a redistribution line which is electrically connected to the bonding pad, on the dielectric layer; and
forming an external terminal which is electrically connected to the bonding pad without using a solder mask which limits a position of the external terminal, on the redistribution line.

2. The method of claim 1, wherein:
forming the redistribution line comprises forming a bent line, and
forming the external terminal comprises forming a protrusion which is extended along the bent line and is limited in the bent line.

3. The method of claim 2, wherein forming the external terminal comprises directly forming the external terminal with surface tension on the redistribution line without forming a region which limits a formation position of the external terminal, by exposing a portion of the redistribution line.

4. The method of claim 1, wherein forming the external terminal comprises attaching a solder ball onto the redistribution line, and applying at least one of heat and a magnetic field to the solder ball to perform the reflow of the solder ball.

5. The method of claim 4, wherein applying the heat uses an induction heater which is adjusted at a frequency of 10 MHz or higher and a power of 2000 Watt or higher.

6. The method of claim 1, wherein forming the external terminal comprises:
providing a solder ball including a non-melting material having a first melting point and a melting material having a second melting point lower than the first melting point, to the redistribution line; and
selectively melting the melting material.

7. The method of claim 6, wherein forming the external terminal comprises selectively melting the melting material to restrictively wet the melting material on the redistribution line without melting the non-melting material.

8. The method of claim 7, wherein in the restrictive wetting of the melting material,
the non-melting material is not melted, and the selectively-melted melting material is not infinitely wetted on the redistribution line by adhesive strength with the non-melting material.

9. The method of claim 6, wherein forming the external terminal comprises heating the solder ball at an intermediate temperature between the first and second melting points.

10. The method of claim 6, wherein providing the solder ball comprises attaching a solder ball having a structure in which the melting material surrounds the non-melting material, onto the redistribution line.

11. The method of claim 1, further comprising forming a molding layer which covers the redistribution line and exposes a portion of the external terminal.

12-20. (canceled)
